(19) United States
(12) Patent Application Publication
(10) Pub. No.: US 2025/0275408 A1
(43) Pub. Date: Aug. 28, 2025

(54) DISPLAY APPARATUS HAVING PIXEL AREAS

(71) Applicant: LG Display Co., Ltd., Seoul (KR)

(72) Inventors: Ki Woong SONG, Paju-si (KR); Hyun Haeng LEE, Paju-si (KR)

(21) Appl. No.: 19/000,131

(22) Filed: Dec. 23, 2024

(30) Foreign Application Priority Data
Feb. 28, 2024 (KR) 10-2024-0028797

(51) Int. Cl. H10K 59/131; H10K 59/121; H10K 59/35

(52) U.S. Cl. CPC H10K 59/1315; H10K 59/1213; H10K 59/351

(57) ABSTRACT

A display apparatus including pixel areas is provided. The pixel areas can be disposed between first/second gate lines. Each of the pixel areas can include a first sub-pixel controlled by the first gate line and a second sub-pixel controlled by the second gate line. The second sub-pixel can display a different color from the first sub-pixel of the corresponding pixel area. The first/second sub-pixel of each pixel area can include a first/second driving circuit disposed close to the first/second gate line. The second driving circuit of each pixel area can share a data line with the first driving circuit of adjacent pixel area. The second driving circuit of each pixel area can have a symmetrical arrangement with the first driving circuit of adjacent pixel area. Thus, the deviation in the coupling capacitance occurring between each driving circuit and the gate line coupled to the corresponding driving circuit can be reduced.

### CROSS-REFERENCE TO RELATED APPLICATIONS

This application claims the benefit of Korean Patent Application No. 10-2024-0028797, filed on Feb. 28, 2024, which is hereby incorporated by reference as if fully set forth herein.

### BACKGROUND

### Technical Field

The present disclosure relates to a display apparatus in which each of pixel areas is electrically connected to a pad area by one of link wirings.

### Description of the Related Art

Generally, a display apparatus provides an image to a user. For example, the display apparatus can include a plurality of pixel areas. Each of the pixel areas can realize various colors. For example, each of the pixel areas can include a plurality of sub-pixels. The sub-pixels in each pixel area can display different colors. For example, each of the pixel areas can include a first sub-pixel and a second sub-pixel displaying a different color from the first sub-pixel.

The second sub-pixel of each pixel area can be controlled independently of the first sub-pixel of the corresponding pixel area. For example, the first sub-pixel of each pixel area can include a first driving circuit, and the second sub-pixel of each pixel area can include a second driving circuit. The first sub-pixel and the second sub-pixel of each pixel area can be controlled by different gate signals. For example, the first driving circuit of each pixel area can be electrically connected to a first gate line, and the second driving circuit of each pixel area can be electrically connected to a second gate line.

The pixel areas can be disposed between the first gate line and the second gate line. Thus, the second driving circuit of each pixel area can have a different arrangement from the first driving circuit of the corresponding pixel area. For example, each of the first driving circuit and the second driving circuit in each pixel area can include a driving thin film transistor, and a distance between the driving thin film transistor of the second driving circuit and the second gate line can be different from a distance between the driving thin film transistor of the first driving circuit and the first gate linc.

### BRIEF SUMMARY

In a display apparatus, a coupling capacitance can occur between each driving circuit and the gate line electrically connected to the corresponding driving circuit. The coupling capacitance can be proportional to the distance between the driving thin film transistor of each driving circuit and the gate line electrically connected to the corresponding driving circuit. Thus, in the display apparatus, the second sub-pixel of each pixel area can have a coupling capacitance different from the first sub-pixel of the corresponding pixel arca. That is, in the display apparatus, the light emitted from the second sub-pixel of each pixel area can have a different luminance from the light emitted from the first sub-pixel of the corresponding pixel area. Therefore, according to the display apparatus in the related art, the quality of the image may decrease due to the deviation in the luminance of the light emitted from the sub-pixels in each pixel area. Accordingly, the present disclosure is directed to a display apparatus that substantially obviates one or more problems due to limitations and disadvantages of the related art.

Various embodiments of the present disclosure provide a display apparatus capable of reducing the deviation in the luminance of the light emitted from the sub-pixels of each pixel area.

Various embodiments of the present disclosure provide a display apparatus capable of reducing the deviation in the coupling capacitance of the sub-pixels in cach pixel area.

Additional advantages, technical benefits, and features of the disclosure will be set forth in part in the description which follows and in part will become apparent to those having ordinary skill in the art upon examination of the following or can be learned from practice of the disclosure. Other advantages of the disclosure can be realized and attained by the structure particularly pointed out in the written description and claims hereof as well as the appended drawings.

To achieve these advantages, as embodied and broadly described herein, there is provided a display apparatus comprising a first gate line, a first data line and a second gate line. The first gate line and the second gate line extend in a first direction. The second gate line is disposed parallel to the first gate line. The data line extends in a second direction. The second direction is perpendicular to the first direction. The data line crosses the first gate line and the second gate linc. A first driving circuit of first sub-pixel is electrically connected to the first gate line and the first data line. A second driving circuit of a second sub-pixel is electrically connected to the first data line and the second gate line. The first data line crosses between the first sub-pixel and the second sub-pixel. A first emission area of the first sub-pixel is disposed between the first driving circuit and the second gate line. A second emission area of the second sub-pixel is disposed between the first gate line and the second driving circuit. The second emission area displays a different color from the first emission area. The second driving circuit has a symmetrical arrangement with the first driving circuit.

The second emission area can be disposed in a first direction with the first emission area.

Each of the first driving circuit and the second driving circuit can include a driving thin film transistor. A gate electrode of the driving thin film transistor can be disposed parallel to the first gate line and the second gate line.

A semiconductor pattern of the driving thin film transistor can be disposed parallel to the first data line.

A second data line can be disposed parallel to the first data line. A third driving circuit of a third sub-pixel can be electrically connected to the first gate line and the second data line. A fourth driving circuit of a fourth sub-pixel can be electrically connected to the second data line and the second gate line. The first sub-pixel can be disposed between the second data line and the third sub-pixel. The fourth sub-pixel can be disposed between the second sub-pixel and the first data line. The fourth driving circuit can be disposed in a first direction with the second driving circuit. The third driving circuit can be disposed in the first direction with the first driving circuit. The fourth driving circuit can have a symmetrical arrangement with the third driving circuit.

The third driving circuit can have a symmetrical arrangement with the first driving circuit, and the fourth driving circuit has a symmetrical arrangement with the second driving circuit.

A third emission area of the third sub-pixel can be disposed between the third driving circuit and the second gate line. The third emission area can display a different color from the first emission area and the second emission area. A fourth emission area of the fourth sub-pixel can be disposed between the first gate line and the fourth driving circuit. The fourth emission area can display a different color from the first emission area, the second emission area and the third emission area.

Reference voltage supply lines can be disposed parallel to the first data line and the second data line. The first sub-pixel and the third sub-pixel can be disposed between one of the reference voltage supply lines and the second data line. The second sub-pixel and the fourth sub-pixel can be disposed between one of the reference voltage supply lines and the first data line.

In another embodiment, there is provided a display apparatus comprising first data lines crossing a first gate line. Second data lines are disposed between the first data lines. The second data lines cross the first gate line. A second gate line extending parallel to the first gate line crosses the first data lines and the second data lines. Pixel areas are disposed between the first data lines and the second data lines. Each of the pixel areas includes a first sub-pixel and a second sub-pixel disposed along the first gate line and the second gate line. A first emission area of the first sub-pixel is disposed between a first driving circuit of the first sub-pixel and the second gate line. A second emission area of the second sub-pixel is disposed between the first gate line and a second driving circuit of the second sub-pixel. The first driving circuit is electrically connected to one of the first data lines and the first gate line. The second driving circuit is electrically connected to one of the second data lines and the second gate line. The second driving circuit has a symmetrical arrangement with the first driving circuit.

The second sub-pixel of each pixel area can display a different color from the first sub-pixel of the corresponding pixel area. The first sub-pixel of each pixel area can display the same or substantially the same color as the first sub-pixel of adjacent pixel area. The second sub-pixel of cach pixel area can display the same or substantially the same color as the second sub-pixel of adjacent pixel arca.

Each of the first sub-pixel and the second sub-pixel in each pixel area can include a first switching thin film transistor and a second switching thin film transistor. A semiconductor pattern of the first switching thin film transistor can cross the first gate line or the second gate linc.

The first emission area and the second emission area of each pixel area can be disposed between the first gate line and the second gate line.

A gate electrode of the second switching thin film transistor can have a shape protruding from the first gate line or the second gate line.

A semiconductor pattern of the second switching thin film transistor can be disposed parallel to the first gate line and the second gate line.

Reference voltage supply lines can be disposed between the first data lines and the second data lines. The reference voltage supply lines can cross the first gate line and the second gate line. Each of the reference voltage supply lines can cross between the first sub-pixel and the second sub-pixel in one of the pixel areas.

Each of the reference voltage supply lines can include a main wiring, an auxiliary wiring and a connection wiring. The auxiliary wiring can be disposed parallel to the main wiring. The connection wiring can be disposed between the main wiring and the auxiliary wiring. The auxiliary wiring can be electrically connected to the main wiring through the connection wiring. Each of the first sub-pixel and the second sub-pixel can include a light-emitting device overlapping with the corresponding emission area. A first electrode of each light-emitting device can include a portion overlapping with the auxiliary wiring.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of R region in FIG. 1;

FIG. 4 is an enlarged view of K1 region in FIG. 3;

FIG. 5 is an enlarged view of K2 region in FIG. 3;

FIG. 6 is a view taken along I-I′ of FIG. 4; and

FIGS. 7 and 8 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiments

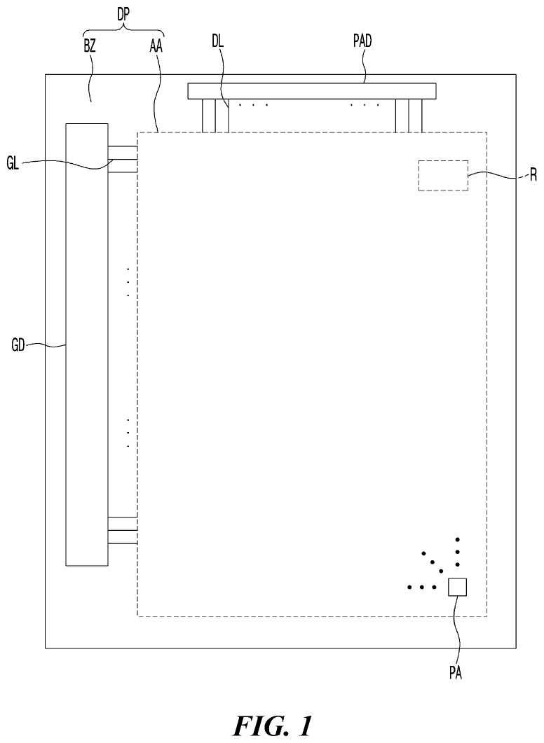

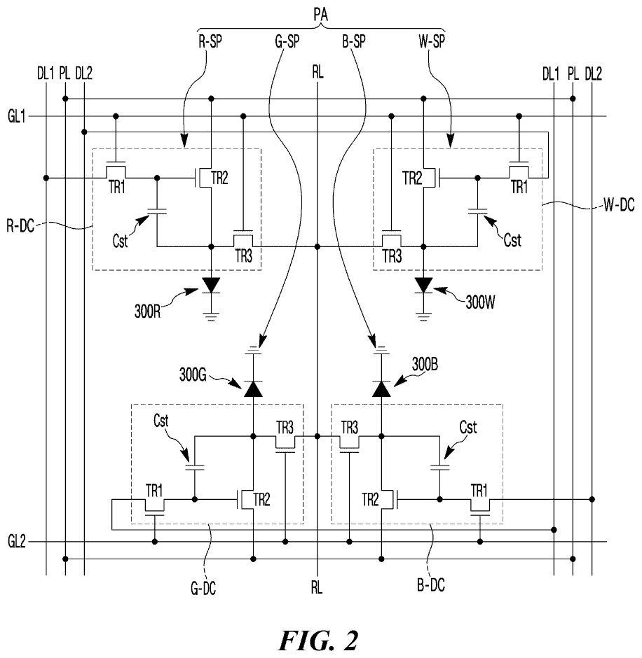

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, pixel areas PA and signal wirings GL1, GL2, DL1, DL2, PL and RL can be disposed in the display panel DP. Various signals can be provided in each pixel area PA through the signal wirings GL1, GL2, DL1, DL2, PL and RL. For example, the signal wirings GL1, GL2, DL1, DL2, PL and RL can include gate lines GL1 and GL2 applying a gate signal, data lines DL1 and DL2 applying a data signal, power voltage supply lines PL supplying a power voltage and reference voltage supply lines RL supplying a reference voltage. The data lines DL1 and DL2 can extend in a direction crossing the gate lines GL1 and GL2. The power voltage supply lines PL and the reference voltage supply lines RL can extend parallel to the data lines DL1 and DL2.

The gate lines GL1 and GL2 can be electrically connected to a gate driver GD. The data lines DL1 and DL2 can be electrically connected to a data driver DD. The gate driver GD and the data driver DD can be electrically connected to a timing controller TC. The gate driver GD and the data driver DD can be controlled by the timing controller TC. For example, the gate driver GD can receive clock signals, reset signals and a start signal from the timing controller TC, and the data driver DD can receive digital video data and a source timing signal from the timing controller TC. The power voltage supply lines PL and the reference voltage supply lines RL can be electrically connected to a power unit PU.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD, the data driver DD, the timing controller TC and the power unit PU can be disposed outside the active area AA. For example, each of the signal wirings GL1, GL2, DL1, DL2, PL and RL can include a region disposed on the bezel area BZ. At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

The pixel areas PA can be disposed side by side in a first direction and a second direction. The second direction can be a direction perpendicular to the first direction. Each of the pixel areas PA can realize various colors. For example, each of the pixel areas PA can include a plurality of sub-pixels R-SP, G-SP, W-SP and B-SP. The sub-pixels R-SP, G-SP, W-SP and B-SP in each pixel area PA can display different colors. For example, each of the pixel area PA can include a red sub-pixel R-SP displaying red color, a green sub-pixel G-SP displaying green color, a white sub-pixel W-SP displaying white color, and a blue sub-pixel B-SP displaying blue color.

The sub-pixels R-SP, G-SP, W-SP and B-SP of each pixel area PA can be controlled by signals applied through the signal wirings GL1, GL2, DL1, DL2, PL and RL. For example, a driving circuit R-DC, G-DC, W-DC and B-DC electrically connected to a light-emitting device 300R, 300G, 300W and 300B can be disposed in each sub-pixel R-SP, G-SP, W-SP and B-SP of cach pixel arca PA.

The driving circuit R-DC, G-DC, W-DC and B-DC of each sub-pixel R-SP, G-SP, W-SP and B-SP can control the light-emitting device 300R, 300G, 300W and 300B of the corresponding sub-pixel R-SP, G-SP, W-SP and B-SP by a signal applied through the signal wirings GL1, GL2, DL1, DL2, PL and RL. The driving circuit R-DC, G-DC, W-DC and B-DC of each sub-pixel R-SP, G-SP, W-SP and B-SP can be electrically connected to one of the gate lines GL1 and GL2, one of the data lines DL1 and DL2, one of the power voltage supply lines PL, and one of the reference voltage supply lines RL. For example, the driving circuit R-DC, G-DC, W-DC and B-DC of each sub-pixel R-SP, G-SP, W-SP and B-SP can supply a driving current corresponding to the data signal to the light-emitting device 300R, 300G, 300W and 300B of the corresponding sub-pixel R-SP, G-SP, W-SP and B-SP according to the gate signal. The driving current supplied by the driving circuit R-DC, G-DC, W-DC and B-DC of each sub-pixel R-SP, G-SP, W-SP and B-SP can be maintained for one frame. The driving circuit R-DC, G-DC, W-DC and B-DC of each sub-pixel R-SP, G-SP, W-SP and B-SP can have a same or substantially same structure. For example, the driving circuit R-DC, G-DC, W-DC and B-DC of each sub-pixel R-SP, G-SP, W-SP and B-SP can include a first thin film transistor TR1, a second thin film transistor TR2, a third thin film transistor TR3 and a storage capacitor Cst.

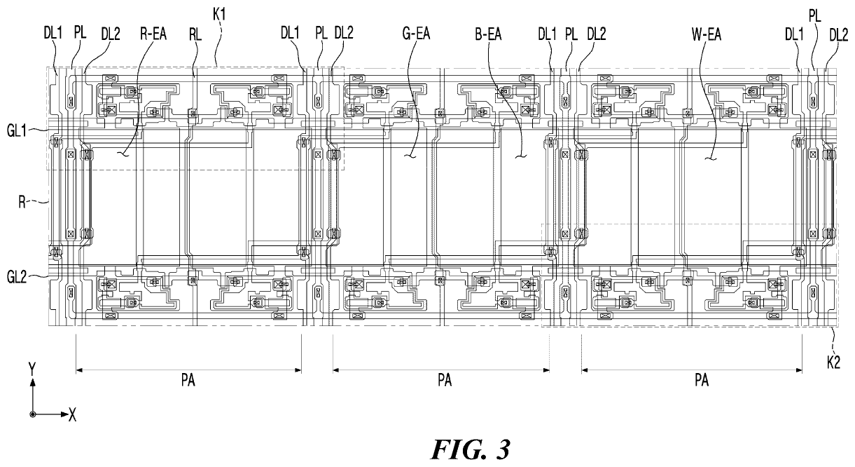

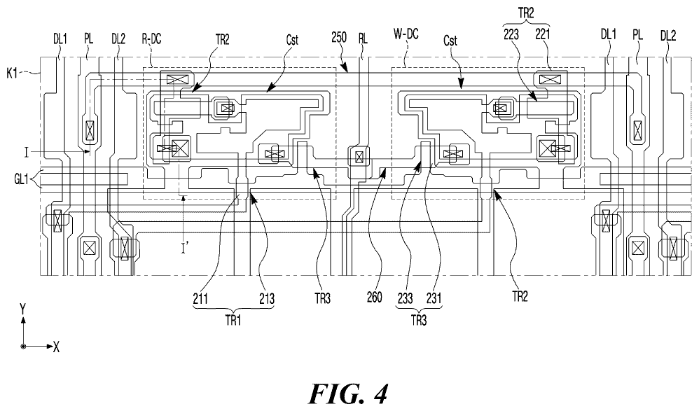

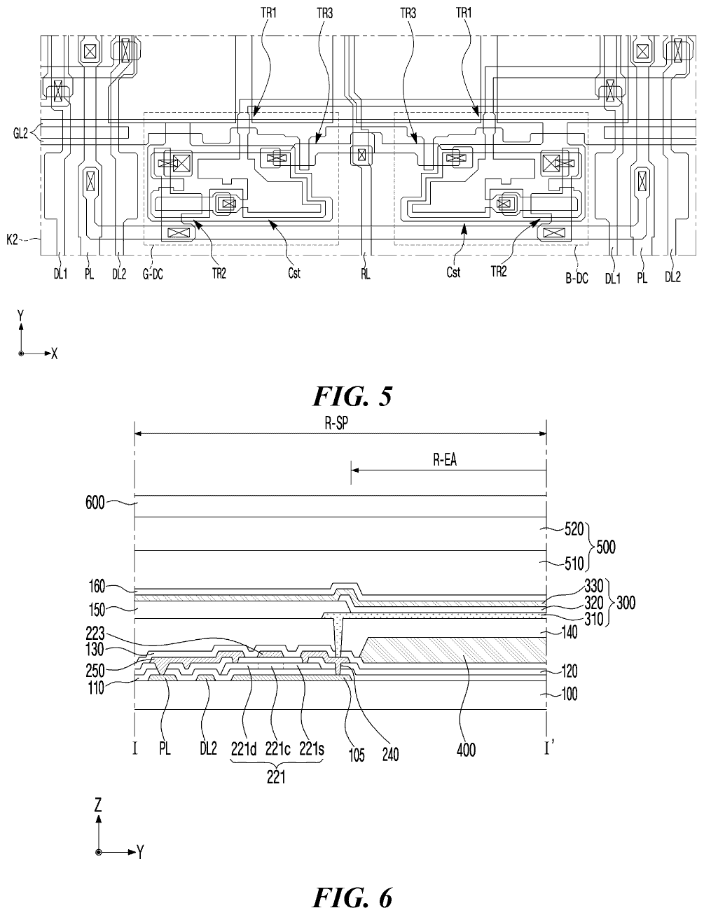

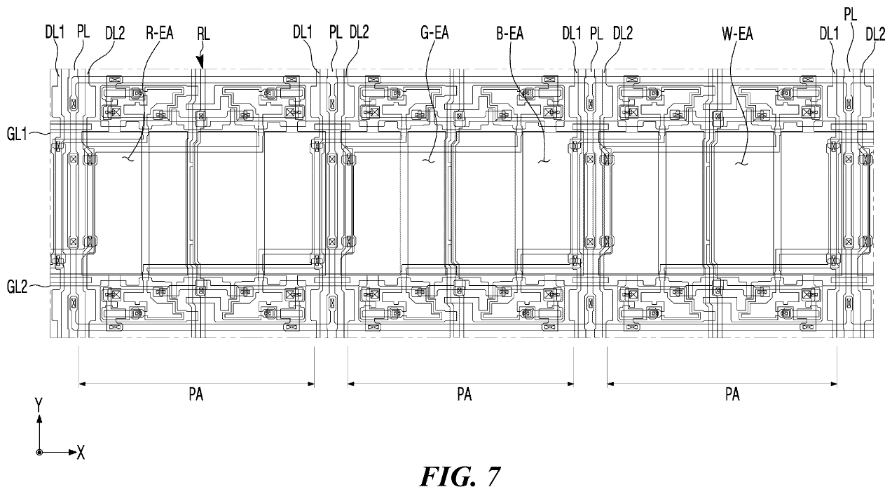

FIG. 3 is an enlarged view of R region in FIG. 1. FIG. 4 is an enlarged view of K1 region in FIG. 3. FIG. 5 is an enlarged view of K2 region in FIG. 3. FIG. 6 is a view taken along I-I′ of FIG. 4.

Referring to FIGS. 2 to 6, the first thin film transistor TR1 of each sub-pixel R-SP, G-SP, W-SP and B-SP can transmit the data signal to the second thin film transistor TR2 of the corresponding sub-pixel R-SP, G-SP, W-SP and B-SP according to the gate signal. For example, the first thin film transistor TR1 of each sub-pixel R-SP, G-SP, W-SP and B-SP can function as a switching thin film transistor. The first thin film transistor TR1 of each sub-pixel R-SP, G-SP, W-SP and B-SP can include a first semiconductor pattern 211 and a first gate electrode 213. The first semiconductor pattern 211 of each sub-pixel R-SP, G-SP, W-SP and B-SP can include a first drain region, a first channel region and a first source region. The first channel region can be disposed between the first drain region and the first source region. The first drain region and the first source region can have a smaller resistance than the first channel region. The first gate electrode 213 of cach sub-pixel R-SP, G-SP, W-SP and B-SP can be disposed on the first channel region of the corresponding sub-pixel R-SP, G-SP, W-SP and B-SP. For example, the first gate electrode 213 of each sub-pixel R-SP, G-SP, W-SP and B-SP can be electrically connected to the corresponding gate line GL1 and GL2, and the first drain region of each sub-pixel R-SP, G-SP, W-SP and B-SP can be electrically connected to the corresponding date line DL1 and DL2.

The second thin film transistor TR2 of cach sub-pixel R-SP, G-SP, W-SP and B-SP can generate the driving current corresponding to the data signal. For example, the second thin film transistor TR2 of each sub-pixel R-SP, G-SP, W-SP and B-SP can function as a driving thin film transistor. The second thin film transistor TR2 of each sub-pixel R-SP, G-SP, W-SP and B-SP can have a same or substantially same structure as the first thin film transistor TR1 of the corresponding sub-pixel R-SP, G-SP, W-SP and B-SP. For example, the second thin film transistor TR2 of each sub-pixel R-SP, G-SP, W-SP and B-SP can include a second semiconductor pattern 221 and a second gate electrode 223.

The second semiconductor pattern 221 of each sub-pixel R-SP, G-SP, W-SP and B-SP can include a semiconductor material. For example, the second semiconductor pattern 221 of cach sub-pixel R-SP, G-SP, W-SP and B-SP can include low-temperature poly-Si (LPTS) or an oxide semiconductor, such as IGZO. The second semiconductor pattern 221 of each sub-pixel R-SP, G-SP, W-SP and B-SP can include a second drain region 221d, a second channel region 221c and a second source region 221s. The second channel region 221c can be disposed between the second drain region 221d and the second source region 221s. The second drain region 221d and the second source region 221s can have a resistance smaller than the second channel region 221c. For example, the second drain region 221d and the second source region 221s can include a conductive region of an oxide semiconductor. The second channel region 221c can be a region of an oxide semiconductor, which is not conductorized.

The first semiconductor pattern 211 of each sub-pixel R-SP, G-SP, W-SP and B-SP can include the same or substantially the same material as the second semiconductor pattern 221 of the corresponding sub-pixel R-SP, G-SP, W-SP and B-SP. The first semiconductor pattern 211 of cach sub-pixel R-SP, G-SP, W-SP and B-SP can be disposed on the same or substantially the same layer as the second semiconductor pattern 221 of the corresponding sub-pixel R-SP, G-SP, W-SP and B-SP. The first semiconductor pattern 211 of each sub-pixel R-SP, G-SP, W-SP and B-SP can be formed by a same process as the second semiconductor pattern 221 of the corresponding sub-pixel R-SP, G-SP, W-SP and B-SP. The first semiconductor pattern 211 of each sub-pixel R-SP, G-SP, W-SP and B-SP can be formed simultaneously with the second semiconductor pattern 221 of the corresponding sub-pixel R-SP, G-SP, W-SP and B-SP. The second drain region 221d of each sub-pixel R-SP, G-SP, W-SP and B-SP can be electrically connected to one of the power voltage supply lines PL.

The second gate electrode 223 of each sub-pixel R-SP, G-SP, W-SP and B-SP can be disposed on the second semiconductor pattern 221 of the corresponding sub-pixel R-SP, G-SP, W-SP and B-SP. For example, the second gate electrode 223 of each sub-pixel R-SP, G-SP, W-SP and B-SP can overlap the second channel region 221c of the corresponding sub-pixel R-SP, G-SP, W-SP and B-SP. The second drain region 221d and the second source region 221s of each sub-pixel R-SP, G-SP, W-SP and B-SP can be disposed outside the second gate electrode 223 of the corresponding sub-pixel R-SP, G-SP, W-SP and B-SP. The second gate electrode 223 of cach sub-pixel R-SP, G-SP, W-SP and B-SP can include a conductive material. For example, the second gate electrode 223 of cach sub-pixel R-SP, G-SP, W-SP and B-SP can include a metal, such as aluminum (Al), chrome (Cr), copper (Cu), molybdenum (Mo), titanium (Ti) and tungsten (W). The second gate electrode 223 of each sub-pixel R-SP, G-SP, W-SP and B-SP can be spaced apart from the second semiconductor pattern 221 of the corresponding sub-pixel R-SP, G-SP, W-SP and B-SP. The second gate electrode 223 of each sub-pixel R-SP, G-SP, W-SP and B-SP can be insulated from the second semiconductor pattern 221 of the corresponding sub-pixel R-SP, G-SP, W-SP and B-SP. For example, the second channel region 221c of cach sub-pixel R-SP, G-SP, W-SP and B-SP can have an electrical conductivity corresponding to a voltage applied to the second gate electrode 223 of the corresponding sub-pixel R-SP, G-SP, W-SP and B-SP. The second gate electrode 223 of cach sub-pixel R-SP, G-SP, W-SP and B-SP can be electrically connected to the first source region of the corresponding sub-pixel R-SP, G-SP, W-SP and B-SP.

The first gate electrode 213 of cach sub-pixel R-SP, G-SP, W-SP and B-SP can include the same or substantially the same material as the second gate electrode 223 of the corresponding sub-pixel R-SP, G-SP, W-SP and B-SP. The first gate electrode 213 and the second gate electrode 223 of cach sub-pixel R-SP, G-SP, W-SP and B-SP can be disposed on a same layer. The first gate electrode 213 of each sub-pixel R-SP, G-SP, W-SP and B-SP can be formed by the same or substantially the same process as the second gate electrode 223 of the corresponding sub-pixel R-SP, G-SP, W-SP and B-SP. For example, the first gate electrode 213 and the second gate electrode 223 of each sub-pixel R-SP, G-SP, W-SP and B-SP can be formed simultaneously.

The storage capacitor Cst of each sub-pixel R-SP, G-SP, W-SP and B-SP can maintain a voltage applied to the second gate electrode 223 of the corresponding sub-pixel R-SP, G-SP, W-SP and B-SP for one frame. For example, the storage capacitor Cst of each sub-pixel R-SP, G-SP, W-SP and B-SP can be electrically connected to the second source region 221s and the second gate electrode 223 of the corresponding sub-pixel R-SP, G-SP, W-SP and B-SP. The storage capacitor Cst of each sub-pixel R-SP, G-SP, W-SP and B-SP can have a stacked structure of capacitor electrodes. For example, the storage capacitor Cst of each sub-pixel R-SP, G-SP, W-SP and B-SP include a first capacitor electrode electrically connected to the second source region 221s of the corresponding sub-pixel R-SP, G-SP, W-SP and B-SP and a second capacitor electrode electrically connected to the second gate electrode 223 of the corresponding sub-pixel R-SP, G-SP, W-SP and B-SP. At least one of the first capacitor electrode and the second capacitor electrode in cach sub-pixel R-SP, G-SP, W-SP and B-SP can be formed by using a process of forming the second thin film transistor TR2 of the corresponding sub-pixel R-SP, G-SP, W-SP and B-SP. Thus, in the display apparatus according to the embodiment of the present disclosure, a process of forming the driving circuit R-DC, G-DC, W-ED and B-DC in cach sub-pixel R-SP, G-SP, W-SP and B-SP can be simplified.

The third thin film transistor TR3 of cach sub-pixel R-SP, G-SP, W-SP and B-SP can initialize the storage capacitor Cst of the corresponding sub-pixel R-SP, G-SP, W-SP and B-SP according to the gate signal. For example, the reference voltage can be applied to the storage capacitor Cst of each sub-pixel R-SP, G-SP, W-SP and B-SP by the third thin film transistor TR3 of the corresponding sub-pixel R-SP, G-SP, W-SP and B-SP according to the gate signal. The third thin film transistor TR3 of cach sub-pixel R-SP, G-SP, W-SP and B-SP can function as a switching thin film transistor. The third thin film transistor TR3 of cach sub-pixel R-SP, G-SP, W-SP and B-SP can have the same or substantially the same structure as the first thin film transistor TR1 of the corresponding sub-pixel R-SP, G-SP, W-SP and B-SP. For example, the third thin film transistor TR3 of cach sub-pixel R-SP, G-SP, W-SP and B-SP can include a third semiconductor pattern 231 and a third gate electrode 233. The third gate electrode 233 of each sub-pixel R-SP, G-SP, W-SP and B-SP can include a third drain region, a third channel region and a third source region. The third gate electrode 233 of each sub-pixel R-SP, G-SP, W-SP and B-SP can be electrically connected to the corresponding gate line GL1 and GL2, the third drain region of each sub-pixel R-SP, G-SP, W-SP and B-SP can be electrically connected to the corresponding reference voltage supply line RL. The gate line GL1 and GL2 electrically connected to the third gate electrode 233 of each sub-pixel R-SP, G-SP, W-SP and B-SP can be the same or substantially the same as the gate line GL1 and GL2 electrically connected to the first gate electrode 213 of the corresponding sub-pixel R-SP, G-SP, W-SP and B-SP. For example, the first thin film transistor TR1 and the third thin film transistor TR3 of each sub-pixel R-SP, G-SP, W-SP and B-SP can be turned on/off simultaneously.

The light-emitting device 300R, 300G, 300W and 300B of each sub-pixel R-SP, G-SP, W-SP and B-SP can emit light displaying a specific color according to the driving current applied by the driving circuit R-DC, G-DC, W-DC and B-DC of the corresponding sub-pixel R-SP, G-SP, W-SP and B-SP. The light-emitting device 300R, 300G, 300W and 300B of each sub-pixel R-SP, G-SP, W-SP and B-SP can have a same or substantially same structure. For example, the light-emitting device 300R, 300G, 300W and 300B of each sub-pixel R-SP, G-SP, W-SP and B-SP can include a first electrode 310, a light-emitting layer 320 and a second electrode 330, which are sequentially stacked.

The first electrode 310 can include a conductive material. The first electrode 310 can include a material having a high transmittance. For example, the first electrode 310 can be a transparent electrode made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material or a hybrid emission material. For example, the display apparatus according to the embodiment of the present disclosure can be an organic light-emitting display apparatus including an organic emission material. The light-emitting layer 320 can have a multi-layer structure. For example, the light-emitting layer 320 can at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting layer 320 can be improved.

The second electrode 330 can include a conductive material. The second electrode 330 can include a different material from the first electrode 310. A reflection of the second electrode 330 can be greater than a reflection of the first electrode 310. For example, the second electrode 330 can include a metal, such as aluminum (Al) and silver (Ag). Thus, in the display apparatus according to the embodiment of the present disclosure, the light generated by the light-emitting layer 320 can be emitted outside through the first electrode 310. The second electrode 330 can have a lower work-function than the first electrode 310. For example, the first electrode 310 can function as anode, and the second electrode 330 can function as cathode.

The light-emitting device 300R, 300G, 300W and 300B and the driving circuit R-DC, G-DC, W-DC and B-DC of each sub-pixel R-SP, G-SP, W-SP and B-SP can be disposed on a device substrate 100. The device substrate 100 can include an insulating material. For example, the device substrate 100 can include glass or plastic.

A plurality of insulating layers 110, 120, 130, 140 and 150 for reducing or preventing unnecessary electrical connection can be disposed on the device substrate 100. For example, a buffer insulating layer 110, a gate insulating layer 120, a device passivation layer 130, a planarization layer 140 and a bank insulating layer 150 can be disposed on the device substrate 100.

The buffer insulating layer 110 can be disposed on the device substrate 100. The buffer insulating layer 110 can reduce or prevent the pollution due to the device substrate 100 in a process of forming the driving circuit R-DC, G-DC, W-DC and B-DC of cach sub-pixel R-SP, G-SP, W-SP and B-SP. For example, an upper surface of the device substrate 100 toward the driving circuit R-DC, G-DC, W-DC and B-DC of cach sub-pixel R-SP, G-SP, W-SP and B-SP can be completely covered by the buffer insulating layer 110. The driving circuit R-DC, G-DC, W-DC and B-DC of each sub-pixel R-SP, G-SP, W-SP and B-SP can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

A light-blocking pattern 105 can be disposed between the device substrate 100 and the buffer insulating layer 110 of each sub-pixel R-SP, G-SP, W-SP and B-SP. The light-blocking pattern 105 of each sub-pixel R-SP, G-SP, W-SP and B-SP can include a material capable of blocking light. For example, the light-blocking pattern 105 of each sub-pixel R-SP, G-SP, W-SP and B-SP can include a metal, such as aluminum (Al), chrome (Cr), copper (Cu), molybdenum (Mo), titanium (Ti) and tungsten (W). The light-blocking pattern 105 of each sub-pixel R-SP, G-SP, W-SP and B-SP can overlap the second semiconductor pattern 221 of the corresponding sub-pixel R-SP, G-SP, W-SP and B-SP. Thus, in the display apparatus according to the embodiment of the present disclosure, the light travelling toward the second semiconductor pattern 221 of each sub-pixel R-SP, G-SP, W-SP and B-SP passing through the device substrate 100 can be blocked by the light-blocking pattern 105 of the corresponding sub-pixel R-SP, G-SP, W-SP and B-SP. Therefore, in the display apparatus according to the embodiment of the present disclosure, the change in the characteristics of the second thin film transistor TR2 in cach sub-pixel R-SP, G-SP, W-SP and B-SP due to an external light can be reduced or prevented.

A specific voltage can be applied to the light-blocking pattern 105 of each sub-pixel R-SP, G-SP, W-SP and B-SP. For example, a source connection electrode 240 for electrically connecting the light-blocking pattern 105 to the second source region 221s can be disposed in sub-pixel R-SP, G-SP, W-SP and B-SP. The source connection electrode 240 of sub-pixel R-SP, G-SP, W-SP and B-SP can include a conductive material. The source connection electrode 240 of cach sub-pixel R-SP, G-SP, W-SP and B-SP can include a material having a relative low resistance. For example, the source connection electrode 240 of each sub-pixel R-SP, G-SP, W-SP and B-SP can include a metal, such as aluminum (Al), chrome (Cr), copper (Cu), molybdenum (Mo), titanium (Ti) and tungsten (W). The source connection electrode 240 of cach sub-pixel R-SP, G-SP, W-SP and B-SP can be disposed on a same layer as the second gate electrode 223 of the corresponding sub-pixel R-SP, G-SP, W-SP and B-SP. The second gate electrode 223 and the source connection electrode 240 of each sub-pixel R-SP, G-SP, W-SP and B-SP can include a same or substantially same material. The source connection electrode 240 of cach sub-pixel R-SP, G-SP, W-SP and B-SP can be formed by the same or substantially the same process as the second gate electrode 223 of the corresponding sub-pixel R-SP, G-SP, W-SP and B-SP. For example, the second gate electrode 223 and the source connection electrode 240 of each sub-pixel R-SP, G-SP, W-SP and B-SP can be formed simultaneously. Thus, in the display apparatus according to the embodiment of the present disclosure, the change in the characteristics of the second thin film transistor TR2 in each sub-pixel R-SP, G-SP, W-SP and B-SP can be effectively reduced or prevented.

The gate insulating layer 120 can be disposed on the buffer insulating layer 110. The first gate electrode 213 of cach sub-pixel R-SP, G-SP, W-SP and B-SP can be insulated from the first semiconductor pattern 211 of the corresponding sub-pixel R-SP, G-SP, W-SP and B-SP by the gate insulating layer 120. The second gate electrode 223 of each sub-pixel R-SP, G-SP, W-SP and B-SP can be insulated from the second semiconductor pattern 221 of the corresponding sub-pixel R-SP, G-SP, W-SP and B-SP by the gate insulating layer 120. The third gate electrode 233 of each sub-pixel R-SP, G-SP, W-SP and B-SP can be insulated from the third semiconductor pattern 231 of the corresponding sub-pixel R-SP, G-SP, W-SP and B-SP by the gate insulating layer 120. For example, the gate insulating layer 120 can cover the first semiconductor pattern 211, the second semiconductor pattern 221 and the third semiconductor pattern 231 of each sub-pixel R-SP, G-SP, W-SP and B-SP. The first gate electrode 213, the second gate electrode 223 and the third gate electrode 233 of cach sub-pixel R-SP, G-SP, W-SP and B-SP can be disposed on the gate insulating layer 120. The source connection electrode 240 of each sub-pixel R-SP, G-SP, W-SP and B-SP can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The device passivation layer 130 can be disposed on the gate insulating layer 120. The device passivation layer 130 can reduce or prevent the damage of the driving circuit R-DC, G-DC, W-DC and B-DC in each sub-pixel R-SP, G-SP, W-SP and B-SP due to the external impact and moisture. For example, the first gate electrode 213, the second gate electrode 223 and the third gate electrode 233 of each sub-pixel R-SP, G-SP, W-SP and B-SP can be covered by the device passivation layer 130. The device passivation layer 130 can include an insulating material. For example, the device passivation layer 130 can be a linear insulating layer made of inorganic insulating material.

The planarization layer 140 can be disposed on the device passivation layer 130. The planarization layer 140 can remove a thickness difference due to the driving circuit R-DC, G-DC, W-DC and B-DC of each sub-pixel R-SP, G-SP, W-SP and B-SP. For example, an upper surface of the planarization layer 140 opposite to the device substrate 100 can be flat. The upper surface of the planarization layer 140 can be parallel to the upper surface of the device substrate 100. The planarization layer 140 can include an insulating material. The planarization layer 140 can include a different material from the device passivation layer 130. The planarization layer 140 can include a material having a relatively high fluidity. For example, the planarization layer 140 can include an organic insulating material.

The bank insulating layer 150 can be disposed on the planarization layer 140. The bank insulating layer 150 can include an insulating material. For example, the bank insulating layer 150 can an organic insulating material. The bank insulating layer 150 can include a different material from the planarization layer 140.

The light-emitting device 300R, 300G, 300W and 300B of each sub-pixel R-SP, G-SP, W-SP and B-SP can be disposed on the planarization layer 140. The first electrode 310 of cach sub-pixel R-SP, G-SP, W-SP and B-SP can be insulated from the first electrode 310 of adjacent sub-pixel R-SP, G-SP, W-SP and B-SP by the bank insulating layer 150. For example, an edge of the first electrode 310 in each sub-pixel R-SP, G-SP, W-SP and B-SP can be covered by the bank insulating layer 150. The first electrode 310 of each sub-pixel R-SP, G-SP, W-SP and B-SP can be partially exposed by the bank insulating layer 150. For example, the bank insulating layer 150 can define an emission arca R-EA, G-EA, W-EA and B-EA in cach sub-pixel R-SP, G-SP, W-SP and B-SP. The light-emitting layer 320 and the second electrode 330 of each sub-pixel R-SP, G-SP, W-SP and B-SP can be stacked on a portion of the first electrode 310 overlapping with the emission arca R-EA, G-EA, W-EA and B-EA of the corresponding sub-pixel R-SP, G-SP, W-SP and B-SP. For example, the light-emitting layer 320 can be in direct contact with the first electrode 310 and the second electrode 330 in the emission arca R-EA, G-EA, W-EA and B-EA of cach sub-pixel R-SP, G-SP, W-SP and B-SP.

The first electrode 310 of each sub-pixel R-SP, G-SP, W-SP and B-SP can be electrically connected to the driving circuit R-DC, G-DC, W-DC and B-DC of the corresponding sub-pixel R-SP, G-SP, W-SP and B-SP. For example, the first electrode 310 of each sub-pixel R-SP, G-SP, W-SP and B-SP can be in direct contact with the source connection electrode of the corresponding sub-pixel R-SP, G-SP, W-SP and B-SP by penetrating the device passivation layer 130 and the planarization layer 140. The device passivation layer 130 and the planarization layer 140 can include pixel contact holes exposing a portion of the source connection electrode 240 in cach sub-pixel R-SP, G-SP, W-SP and B-SP. The first electrode 310 of each sub-pixel R-SP, G-SP, W-SP and B-SP can be electrically connected to the source connection electrode 240 of the corresponding sub-pixel R-SP, G-SP, W-SP and B-SP through one of the pixel contact holes. The pixel contact holes can be disposed outside the emission arca R-EA, G-EA, W-EA and B-EA defined in cach sub-pixel R-SP, G-SP, W-SP and B-SP. For example, the pixel contact holes can overlap the bank insulating layer 150. Thus, in the display apparatus according to the embodiment of the present disclosure, the change in the location of the first electrode 310 within the emission arca R-EA, G-EA, W-EA and B-EA of cach sub-pixel R-SP, G-SP, W-SP and B-SP can be reduced or minimized. For example, a portion of the first electrode 310 overlapping with the emission arca R-EA, G-EA, W-EA and B-EA of cach sub-pixel R-SP, G-SP, W-SP and B-SP can be in direct contact with the upper surface of the planarization layer 140. Therefore, in the display apparatus according to the embodiment of the present disclosure, the luminance deviation according to the generating location of the light emitted from the emission arca R-EA, G-EA, W-EA and B-EA of cach sub-pixel R-SP, G-SP, W-SP and B-SP can be reduced or prevented.

The light emitted from the light-emitting device 300R, 300G, 300W and 300B of cach sub-pixel R-SP, G-SP, W-SP and B-SP can display a different color from the light emitted from the light-emitting device 300R, 300G, 300W and 300B of adjacent sub-pixel R-SP, G-SP, W-SP and B-SP. The light-emitting layer 320 of the light-emitting device 300R, 300G, 300W and 300B in cach sub-pixel R-SP, G-SP, W-SP and B-SP can be spaced apart from the light-emitting layer 320 of the light-emitting device 300R, 300G, 300W and 300B in adjacent sub-pixel R-SP, G-SP, W-SP and B-SP. For example, the light-emitting layer 320 of the light-emitting device 300R, 300G, 300W and 300B in each sub-pixel R-SP, G-SP, W-SP and B-SP can include different materials. The light-emitting layer 320 of the light-emitting device 300R, 300G, 300W and 300B in cach sub-pixel R-SP, G-SP, W-SP and B-SP can have a stacked structure different from the light-emitting layer 320 of the light-emitting device 300R, 300G, 300W and 300B in adjacent sub-pixel R-SP, G-SP, W-SP and B-SP. The light-emitting layer 320 of the light-emitting device 300R, 300G, 300W and 300B in each sub-pixel R-SP, G-SP, W-SP and B-SP can include an end disposed on the bank insulating layer 150.

A voltage applied to the second electrode 330 of each sub-pixel R-SP, G-SP, W-SP and B-SP can be the same or substantially the same as a voltage applied to the second electrode 330 of adjacent sub-pixel R-SP, G-SP, W-SP and B-SP. For example, the second electrode 330 of cach sub-pixel R-SP, G-SP, W-SP and B-SP can be electrically connected to the second electrode 330 of adjacent sub-pixel R-SP, G-SP, W-SP and B-SP. The second electrode 330 of each sub-pixel R-SP, G-SP, W-SP and B-SP can include the same or substantially the same material as the second electrode 330 of adjacent sub-pixel R-SP, G-SP, W-SP and B-SP. The second electrode 330 of cach sub-pixel R-SP, G-SP, W-SP and B-SP can be formed by the same or substantially the same process as the second electrode of adjacent sub-pixel R-SP, G-SP, W-SP and B-SP. For example, the second electrode 330 of each sub-pixel R-SP, G-SP, W-SP and B-SP can be formed simultaneously with the second electrode 330 of adjacent sub-pixel R-SP, G-SP, W-SP and B-SP. The second electrode 330 of each sub-pixel R-SP, G-SP, W-SP and B-SP can be in direct contact with the second electrode 330 of adjacent sub-pixel R-SP, G-SP, W-SP and B-SP. Thus, in the display apparatus according to the embodiment of the present disclosure, a process of forming the second electrode 330 in cach sub-pixel R-SP, G-SP, W-SP and B-SP can be simplified.

A color filter 400 can be disposed on a path of the light emitted from the light-emitting device 300R, 300G, 300W and 300B in cach sub-pixel R-SP, G-SP, W-SP and B-SP. For example, the color filter 400 of cach sub-pixel R-SP, G-SP, W-SP and B-SP can be disposed between the device passivation layer 130 and the planarization layer 140. A thickness difference due to the color filter 400 of each sub-pixel R-SP, G-SP, W-SP and B-SP can be removed by the planarization layer 140. The light passing through the color filter 400 of each sub-pixel R-SP, G-SP, W-SP and B-SP can display the same or substantially the same color as the light generated by the light-emitting device 300R, 300G, 300W and 300B of the corresponding sub-pixel R-SP, G-SP, W-SP and B-SP. Thus, in the display apparatus according to the embodiment of the present disclosure, the color reproduction of the light emitted from each sub-pixel R-SP, G-SP, W-SP and B-SP can be improved.

A capping layer 160 can be disposed on the light-emitting device 300R, 300G, 300W and 300B of each sub-pixel R-SP, G-SP, W-SP and B-SP. The capping layer 160 can reduce or prevent the damage of the light-emitting device 300R, 300G, 300W and 300B in each sub-pixel R-SP, G-SP, W-SP and B-SP. For example, the light-emitting device 300R, 300G, 300W and 300B of cach sub-pixel R-SP, G-SP, W-SP and B-SP can be covered by the capping layer 160. The capping layer 160 can include an insulating material. For example, the capping layer 160 can include an inorganic insulating material and/or an organic insulating material. The capping layer 160 can have a multi-layer structure. For example, the capping layer 160 can have a structure in which an inorganic insulating layer made of an inorganic insulating material and an organic insulating layer made of an organic insulating material are stacked. Thus, in the display apparatus according to the embodiment of the present disclosure, the damage of the light-emitting device 300R, 300G, 300W and 300B in each sub-pixel R-SP, G-SP, W-SP and B-SP can be effectively reduced or prevented by the capping layer 160.

An encapsulating layer 500 and an encapsulation substrate 600 can be stacked on the capping layer 160. The encapsulation substrate 600 can include a different material from the device substrate 100. The encapsulation substrate 600 can include a material having relatively high heat dissipation characteristics. For example, the encapsulation substrate 600 can include a metal, such as aluminum (Al) and nickel (Ni).

The encapsulating layer 500 can include an insulating material. The encapsulating layer 500 can include an adhesive material. For example, the encapsulation substrate 600 can be coupled to the device substrate 100 in which the capping layer 160 is covered by the encapsulating layer 500. The encapsulating layer 500 can block or delay the movement of the external moisture. For example, the encapsulating layer 500 an include absorbing particles. The encapsulating layer 500 can have a multi-layer structure. For example, the encapsulating layer 500 can include a lower encapsulating layer 510 and an upper encapsulating layer 520 disposed on the lower encapsulating layer 510. The lower encapsulating layer 510 can be disposed between the capping layer 160 and the upper encapsulating layer 520. The absorbing particles can be dispersed in the upper encapsulating layer 520. Thus, in the display apparatus according to the embodiment of the present disclosure, the stress applied in a direction of the device substrate 100 due to the expansion of the absorbing particles can be alleviated by the lower encapsulating layer 510. The upper encapsulating layer 520 can include a different material from the lower encapsulating layer 510. Therefore, in the display apparatus according to the embodiment of the present disclosure, the damage of the light-emitting device 300R, 300G, 300W and 300B in each sub-pixel R-SP, G-SP, W-SP and B-SP due to the penetrating of the external moisture and the external impact can be effectively reduced or prevented.

The sub-pixels R-SP, G-SP, W-SP and B-SP of each pixel area PA can be disposed side by side in a first direction. For example, the red sub-pixel R-SP, the green sub-pixel G-SP, the white sub-pixel W-SP and the blue sub-pixel B-SP of each pixel area PA can be disposed side by side in the first direction X. The light-emitting device 300R, 300G, 300W and 300B of each sub-pixel R-SP, G-SP, W-SP and B-SP can be controlled independently. For example, the gate lines GL1 and GL2 can include first gate lines GL1 extending in the first direction X and second gate lines GL2 extending parallel to the first gate lines GL1. The second gate lines GL2 can be disposed between the first gate lines GL1. For example, the emission arca R-EA, G-EA, W-EA and B-EA of cach sub-pixel R-SP, G-SP, W-SP and B-SP can be disposed between one of the first gate lines GL1 and one of the second gate lines GL2. The data lines DL1 and DL2 can include first data lines DL1 extending in the second direction Y and second data lines DL2 extending parallel to the first data lines DL1. One of the first data lines DL1 and one of the second data lines DL2 can be disposed between the pixel areas PA. The power voltage supply lines PL and the reference voltage supply lines RL can extend in the second direction Y. For example, cach of the data lines DL1 and DL2, the power voltage supply lines PL and the reference voltage supply lines RL can cross the first gate lines GL1 and the second gate lines GL2.

Each of the sub-pixels R-SP, G-SP, W-SP and B-SP in each pixel area PA can share the data lines DL1 and DL2 with one of the sub-pixels R-SP, G-SP, W-SP and B-SP in adjacent pixel area PA. For example, one of the first data lines DL1 and one of the second data lines DL2 can cross between the pixel areas PA, a red driving circuit R-DC of the red sub-pixel R-SP in each pixel area PA can be electrically connected to the first data line DL1 disposed on a side of the corresponding pixel area PA, and a green driving circuit G-DC of the green sub-pixel G-SP in cach pixel area PA can be electrically connected to the first data line DL1 disposed on an opposite side of the corresponding pixel area PA. A white driving circuit W-DC of the white sub-pixel W-SP in each pixel area PA can be electrically connected to the second data line DL2 disposed on a side of the corresponding pixel area PA, and a blue driving circuit B-DC of the blue sub-pixel B-SP in each pixel area PA can be electrically connected to the second data line DL2 disposed on an opposite side of the corresponding pixel arca PA. That is, in the display apparatus according to the embodiment of the present disclosure, the red sub-pixel R-SP of each pixel area PA can share one of the first data lines DL1 with the green sub-pixel G-SP of adjacent pixel area PA, and the white sub-pixel W-SP of each pixel area PA can shape one of the second data lines DL2 with the blue sub-pixel B-SP of adjacent pixel arca PA. Thus, in the display apparatus according to the embodiment of the present disclosure, the number of the data lines DL1 and DL2 can be reduced. Therefore, in the display apparatus according to the embodiment of the present disclosure, an area of each sub-pixel R-SP, G-SP, W-SP and B-SP can be increased. For example, in the display apparatus according to the embodiment of the present disclosure, a size of the emission area R-EA, G-EA, W-EA and B-EA defined in each sub-pixel R-SP, G-SP, W-SP and B-SP can be increased.

Each of the sub-pixels R-SP, G-SP, W-SP and B-SP can be electrically connected to the gate line GL1 and GL2 different than the sub-pixel R-SP, G-SP, W-SP and B-SP sharing the data line DL1 and DL2 with the corresponding sub-pixel R-SP, G-SP, W-SP and B-SP. For example, the red sub-pixel R-SP and the white sub-pixel W-SP of each pixel area PA can be electrically connected to one of the first gate lines GL1, and the green sub-pixel G-SP and the blue sub-pixel B-SP of each pixel area PA can be electrically connected to the one of the second gate lines GL2. Thus, in the display apparatus according to the embodiment of the present disclosure, the data signal can be applied simultaneously to the sub-pixels R-SP, G-SP, W-SP and B-SP of each pixel area PA through the data lines DL1 and DL2. That is, in the display apparatus according to the embodiment of the present disclosure, the sub-pixels R-SP, G-SP, W-SP and B-SP of each pixel area PA can operate simultaneously. Therefore, in the display apparatus according to the embodiment of the present disclosure, the decrease in the driving speed due to the operation delay of each pixel arca PA can be reduced or prevented.

The driving circuit R-DC, G-DC, W-DC and B-DC and the emission arca R-EA, G-EA, W-EA and B-EA of each sub-pixel R-SP, G-SP, W-SP and B-SP can be disposed side by side in the second direction Y. The driving circuit R-DC, G-DC, W-DC and B-DC of cach sub-pixel R-SP, G-SP, W-SP and B-SP can be disposed close to the corresponding gate line GL1 and GL2. For example, the red driving circuit R-DC and the white driving circuit W-DC of each pixel arca PA can be disposed close to the corresponding first gate line GL1, and the green driving circuit G-DC and the blue driving circuit B-DC of each pixel area PA can be disposed close to the corresponding second gate line GL2. A red emission area R-EA defined in the red sub-pixel R-SP of each pixel area PA can be disposed between the red driving circuit R-DC of the corresponding pixel arca PA and the corresponding second gate line GL2, and a white emission area W-EA defined in the white sub-pixel W-SP of each pixel area PA can be disposed between the white driving circuit W-DC of the corresponding pixel arca PA and the corresponding second gate line GL2. A green emission arca G-EA defined in the green sub-pixel G-SP of each pixel area PA can be disposed between the corresponding first gate line GL1 and the green driving circuit G-DC of the corresponding pixel arca PA, and a blue emission arca B-EA defined in the blue sub-pixel B-SP of each pixel arca PA can be disposed between the corresponding first gate line GL1 and the blue driving circuit B-DC of the corresponding pixel arca PA.

The sub-pixels R-SP, G-SP, W-SP and B-SP electrically connected to the first gate lines GL1 and the sub-pixels R-SP, G-SP, W-SP and B-SP electrically connected to the second gate lines GL2 can be alternately arranged in cach pixel arca PA. For example, the green sub-pixel G-SP of cach pixel arca PA can be disposed between the red sub-pixel R-SP and the white sub-pixel W-SP of the corresponding pixel area PA, and the white sub-pixel W-SP of each pixel arca PA can be disposed between the green sub-pixel G-SP and the blue sub-pixel B-SP of the corresponding pixel arca PA. Thus, in the display apparatus according to the embodiment of the present disclosure, a space for the driving circuit R-DC, G-DC, W-DC and B-DC of cach sub-pixel R-SP, G-SP, W-SP and B-SP can be sufficiently secured. Therefore, in the display apparatus according to the embodiment of the present disclosure, the decrease in the area of the emission arcas R-EA, G-EA, W-EA and B-EA defined in each pixel area PA due to the driving circuits R-DC, G-DC, W-DC and B-DC of the corresponding pixel area PA can be reduced or minimized.

The driving circuits R-DC, G-DC, W-DC and B-DC of each pixel area PA can be arranged to be symmetrical to each other. For example, the green driving circuit G-DC of each pixel area PA can be arranged to be symmetrical to the red driving circuit R-DC of the corresponding pixel area PA with respect to the first direction X, and the white driving circuit W-DC of each pixel area PA can be arranged to be symmetrical to the blue driving circuit B-DC of the corresponding pixel arca PA with respect to the first direction X. Thus, in the display apparatus according to the embodiment of the present disclosure, the coupling capacitance of the green sub-pixel G-SP in cach pixel area PA can be substantially the same as the coupling capacitance of the red sub-pixel R-SP in the corresponding pixel arca PA, and the coupling capacitance of the blue sub-pixel B-SP in cach pixel area PA can be substantially the same as the coupling capacitance of the white sub-pixel W-SP in the corresponding pixel area PA. The white driving circuit W-DC of each pixel area PA can be arranged to be symmetrical to the red driving circuit R-DC of the corresponding pixel arca PA with respective to the second direction Y, and the blue driving circuit B-DC of each pixel area PA can be arranged to be symmetrical to the green driving circuit G-DC of the corresponding pixel arca PA with respect to the second direction Y. That is, in the display apparatus according to the embodiment of the present disclosure, the coupling capacitance of the white sub-pixel W-SP in cach pixel area PA can be substantially the same as the coupling capacitance of the red sub-pixel R-SP in the corresponding pixel arca PA, and the coupling capacitance of the blue sub-pixel B-SP in cach pixel arca PA can be substantially the same as the coupling capacitance of the green sub-pixel G-SP in the corresponding pixel area PA. Therefore, in the display apparatus according to the embodiment of the present disclosure, the deviation in the luminance of the light emitted from each sub-pixel R-SP, G-SP, W-SP and B-SP due to the difference in the coupling capacitance can be reduced or prevented.

The second thin film transistor TR2 of each sub-pixel R-SP, G-SP, W-SP and B-SP can be disposed far from the emission arca R-EA, G-EA, W-EA and B-EA of the corresponding sub-pixel R-SP, G-SP, W-SP and B-SP. For example, the first gate lines GL1 and the second gate lines GL2 can be disposed between the emission arca R-EA, G-EA, W-EA and B-EA and the second thin film transistor TR2 of cach sub-pixel R-SP, G-SP, W-SP and B-SP. Thus, in the display apparatus according to the embodiment of the present disclosure, the coupling capacitance of each sub-pixel R-SP, G-SP, W-SP and B-SP can be reduced or minimized.

The first semiconductor pattern 211 of each sub-pixel R-SP, G-SP, W-SP and B-SP can have a shape extending in the second direction Y. For example, the first semiconductor pattern 211 of each sub-pixel R-SP, G-SP, W-SP and B-SP can cross one of the first gate lines GL1 and the second gate lines GL2. The first gate lines GL1 and the second gate lines GL2 can be disposed on a same layer as the first gate electrode 213 of each sub-pixel R-SP, G-SP, W-SP and B-SP. For example, the first gate lines GL1 and the second gate lines GL2 can be disposed between the gate insulating layer 120 and the device passivation layer 130. The first gate lines GL1 and the second gate lines GL2 can include the same or substantially the same material as the first gate electrode 213 of each sub-pixel R-SP, G-SP, W-SP and B-SP. The first gate lines GL1 and the second gate lines GL2 can be formed by the same or substantially the same process as the first gate electrode 213 of cach sub-pixel R-SP, G-SP, W-SP and B-SP. For example, the first gate lines GL1 and the second gate lines GL2 can be formed simultaneously with the first gate electrode 213 of each sub-pixel R-SP, G-SP, W-SP and B-SP. The first gate electrode 213 of each sub-pixel R-SP, G-SP, W-SP and B-SP can be in direct contact with one of the first gate lines GL1 and the second gate lines GL2. For example, the first gate electrode 213 of each sub-pixel R-SP, G-SP, W-SP and B-SP can be a portion of the corresponding gate line GL1 and GL2. Thus, in the display apparatus according to the embodiment of the present disclosure, a process of forming the first gate electrode 213 in each sub-pixel R-SP, G-SP, W-SP and B-SP can be simplified.

The second gate electrode 223 of each sub-pixel R-SP, G-SP, W-SP and B-SP can be disposed parallel to the first gate lines GL1 and the second gate lines GL2. The second semiconductor pattern 221 of each sub-pixel R-SP, G-SP, W-SP and B-SP can have a shape extending in the second direction Y. For example, the second semiconductor pattern 221 of each sub-pixel R-SP, G-SP, W-SP and B-SP can be disposed parallel to the data lines DL1 and DL2. Power connection lines 250 extending in the first direction X can be electrically connected to at least one of the power voltage supply lines PL and the second semiconductor pattern 221 of each sub-pixel R-SP, G-SP, W-SP and B-SP can be electrically connected to one of the power connection lines 250. Thus, in the display apparatus according to the embodiment of the present disclosure, the configuration of the driving circuit R-DC, G-DC, W-DC and B-DC in each sub-pixel R-SP, G-SP, W-SP and B-SP can be simplified. That is, in the display apparatus according to the embodiment of the present disclosure, an area occupied by the driving circuit R-DC, G-DC, W-DC and B-DC of each sub-pixel R-SP, G-SP, W-SP and B-SP can be reduced or minimized. Therefore, in the display apparatus according to the embodiment of the present disclosure, a size of each sub-pixel R-SP, G-SP, W-SP and B-SP can be reduced. And, in the display apparatus according to the embodiment of the present disclosure, an area of the emission area R-EA, G-EA, W-EA and B-EA defined in each sub-pixel R-SP, G-SP, W-SP and B-SP can be increased or maximized.

The power connection lines 250 can be disposed on a different layer from the power voltage supply lines PL. The power connection lines 250 can be disposed on a same layer as the source connection electrode 240 of each sub-pixel R-SP, G-SP, W-SP and B-SP. For example, the power connection lines 250 can be disposed between the gate insulating layer 120 and the device passivation layer 130. The power connection lines 250 can include the same or substantially the same material as the source connection electrode 240 of each sub-pixel R-SP, G-SP, W-SP and B-SP. The power connection lines 250 can be formed by the same or substantially the same process as the source connection electrode 240 of each sub-pixel R-SP, G-SP, W-SP and B-SP. For example, the power connection lines 250 can be formed simultaneously with the source connection electrode 240 of each sub-pixel R-SP, G-SP, W-SP and B-SP. Thus, in the display apparatus according to the embodiment of the present disclosure, the decrease in the process efficiency due to the formation of the power connection lines 250 can be reduced or prevented.

The power voltage supply lines PL can be disposed closer to the device substrate 100 than the power connection lines 250. For example, the power voltage supply lines PL can be disposed on a same layer as the light-emitting pattern 105 of each sub-pixel R-SP, G-SP, W-SP and B-SP. The power voltage supply lines PL can include the same or substantially the same material as the light-emitting pattern 105 of each sub-pixel R-SP, G-SP, W-SP and B-SP. The power voltage supply lines PL can be formed by the same or substantially the same process as the light-emitting pattern 105 of each sub-pixel R-SP, G-SP, W-SP and B-SP. For example, the power voltage supply lines PL can be formed simultaneously with the light-emitting pattern 105 of each sub-pixel R-SP, G-SP, W-SP and B-SP. Thus, in the display apparatus according to the embodiment of the present disclosure, a process of forming the power voltage supply lines PL can be simplified.

The data lines DL1 and DL2 can be disposed on a same layer as the power voltage supply lines PL. For example, the data lines DL1 and DL2 can be disposed between the device substrate 100 and the buffer insulating layer 110. The data lines DL1 and DL2 can include the same or substantially the same material as the power voltage supply lines PL. The data lines DL1 and DL2 can be formed by the same or substantially the same process as the power voltage supply lines PL. For example, the data lines DL1 and DL2 can be formed simultaneously with the power voltage supply lines PL. Thus, in the display apparatus according to the embodiment of the present disclosure, a process of forming the data lines DL1 and DL2 can be simplified.

The third thin film transistor TR3 of cach sub-pixel R-SP, G-SP, W-SP and B-SP can be spaced apart from the first thin film transistor TR1 and the second thin film transistor TR2 of the corresponding sub-pixel R-SP, G-SP, W-SP and B-SP. The third semiconductor pattern 231 of each sub-pixel R-SP, G-SP, W-SP and B-SP can have a shape extending in a direction different from the first semiconductor pattern 211 and the second semiconductor pattern 221 of the corresponding sub-pixel R-SP, G-SP, W-SP and B-SP. For example, the third semiconductor pattern 231 of each sub-pixel R-SP, G-SP, W-SP and B-SP can have a shape extending in the first direction X. The third semiconductor pattern 231 of each sub-pixel R-SP, G-SP, W-SP and B-SP can be disposed parallel to the first gate lines GL1 and the second gate lines GL2. The third gate electrode 233 of each sub-pixel R-SP, G-SP, W-SP and B-SP can extend in the second direction Y. The third gate electrode 233 of each sub-pixel R-SP, G-SP, W-SP and B-SP can extending in a direction perpendicular to the first gate lines GL1 and the second gate lines GL2. For example, the third gate electrode 233 of each sub-pixel R-SP, G-SP, W-SP and B-SP can have a shape protruding from one of the first gate lines GL1 and the second gate lines GL2. Thus, in the display apparatus according to the embodiment of the present disclosure, a width of each first gate line GL1 and a width of each second gate line GL2 can be increased. For example, in the display apparatus according to the embodiment of the present disclosure, a resistance of each first gate line GL1 and a resistance of each second gate lines GL2 can be reduced. Therefore, in the display apparatus according to the embodiment of the present disclosure, the delay of the signal applied through the first gate lines GL1 and the second gate lines GL2 can be reduced or prevented.

The reference voltage supply lines RL can be disposed parallel to the power voltage supply lines PL. For example, the reference voltage supply lines RL can extend in the second direction Y. each of the reference voltage supply lines RL can cross one of the pixel areas PA. For example, the red sub-pixel R-SP and the green sub-pixel G-SP of each pixel area PA can be disposed between one of the second data lines DL2 and one of the reference voltage supply lines RL, and the white sub-pixel W-SP and the blue sub-pixel B-SP of each pixel area PA can be disposed between one of the reference voltage supply lines RL and one of the first data lines DL1. Thus, in the display apparatus according to the embodiment of the present disclosure, a process of connecting the third drain region of the third thin film transistor TR3 in cach sub-pixel R-SP, G-SP, W-SP and B-SP to the corresponding reference voltage supply line RL can be simplified.

The reference voltage supply lines RL can be disposed on a same layer as the power voltage supply lines PL. For example, the reference voltage supply lines RL can be disposed between the device substrate 100 and the buffer insulating layer 110. The reference voltage supply lines RL can include the same or substantially the same material as the power voltage supply lines PL. The reference voltage supply lines RL can be formed by the same or substantially the same process as the power voltage supply lines PL. For example, the reference voltage supply lines RL can be formed simultaneously with the power voltage supply lines PL. Thus, in the display apparatus according to the embodiment of the present disclosure, a process of forming the reference voltage supply lines RL can be simplified.

The third drain region of each sub-pixel R-SP, G-SP, W-SP and B-SP can be electrically connected to the corresponding reference voltage supply line RL through one of reference connection lines 260 extending in the first direction X. For example, each of the reference connection lines 260 can be electrically connected to one of the reference voltage supply lines RL. The reference connection lines 260 can be disposed on a different layer from the reference voltage supply lines RL. The reference connection lines 260 can be disposed on a same layer as the power connection lines 250. For example, the reference connection lines 260 can be disposed between the gate insulating layer 120 and the device passivation layer 130. The reference connection lines 260 can include the same or substantially the same material as the power connection lines 250. The reference connection lines 260 can be formed by the same or substantially the same process as the power connection lines 250. For example, the reference connection lines 260 can be formed simultaneously with the power connection lines 250. Thus, in the display apparatus according to the embodiment of the present disclosure, the degradation in the process efficiency due to the formation of the reference connection lines 260 can be reduced or prevented.

Accordingly, the display apparatus according to the embodiment of the present disclosure can include the pixel areas PA disposed between the gate lines GL1 and GL2, the data lines DL1 and DL2, and the power voltage supply lines PL, wherein each of the pixel areas PA can include the sub-pixels R-SP, G-SP, W-SP and B-SP disposed side by side along the gate lines GL1 and GL2, wherein the sub-pixels R-SP and W-SP of each pixel area PA electrically connected to the first gate lines GL1 of the gate lines GL1 and GL2 can share the data lines DL1 and DL2 with the sub-pixels G-SP and B-SP of adjacent pixel area PA electrically connected to the second gate lines GL2 of the gate lines GL1 and GL2, and wherein the driving circuit R-DC, G-DC, W-DC and B-DC of each sub-pixel R-SP, G-SP, W-SP and B-SP can have an arrangement to be symmetrical to the driving circuit R-DC, G-DC, W-DC and B-DC of the sub-pixel R-SP, G-SP, W-SP and B-SP adjacent in the first direction X or the second direction Y. Thus, in the display apparatus according to the embodiment of the present disclosure, the sub-pixels R-SP, G-SP, W-SP and B-SP of cach pixel area PA can have substantially the same coupling capacitance. Therefore, in the display apparatus according to the embodiment of the present disclosure, the degradation in the quality of the image due to the deviation in the luminance of the light emitted from each sub-pixel R-SP, G-SP, W-SP and B-SP can be reduced or prevented.

And, in the display apparatus according to the embodiment of the present disclosure, the coupling capacitance of each sub-pixel R-SP, G-SP, W-SP and B-SP can be substantially the same, without the degradation in the process efficiency. Thus, in the display apparatus according to the embodiment of the present disclosure, the production energy can be reduced by process optimization.

The display apparatus according to the embodiment of the present disclosure is described that the driving circuit R-DC, G-DC, W-DC and B-DC of each sub-pixel R-SP, G-SP, W-SP and B-SP can consist of the first thin film transistor TR1, the second thin film transistor TR2, the third thin film transistor TR3 and the storage capacitor Cst. However, in the display apparatus according to another embodiment of the present disclosure, the driving circuit R-DC, G-DC, W-DC and B-DC of each sub-pixel R-SP, G-SP, W-SP and B-SP can include a driving thin film transistor and at least one switching thin film transistor. For example, in the display apparatus according to another embodiment of the present disclosure, the driving circuit R-DC, G-DC, W-DC and B-DC of cach sub-pixel R-SP, G-SP, W-SP and B-SP can consist of only the first thin film transistor TR1 functioning as a switching thin film transistor, the second thin film transistor TR2 functioning as a driving thin film transistor, and the storage capacitor Cst. Thus, in the display apparatus according to another embodiment of the present disclosure, the degree of freedom in configuring the driving circuit R-DC, G-DC, W-DC and B-DC in each sub-pixel R-SP, G-SP, W-SP and B-SP can be improved.

In the display apparatus according to the embodiment of the present disclosure, the location and the electric connection of the first drain region, the first source region, the second drain region 221d, the second source region 221s, the third drain region and the third source region in each driving circuit R-DC, G-DC, W-DC and B-DC can vary depending on the configuration of the corresponding driving circuit R-DC, G-DC, W-DC and B-DC and/or the type of the corresponding thin film transistors TR1, TR2 and TR3. For example, in the display apparatus according to another embodiment of the present disclosure, the second gate electrode 223 of each driving circuit R-DC, G-DC, W-DC and B-DC can be electrically connected to the first drain region of the corresponding driving circuit R-DC, G-DC, W-DC and B-DC. Thus, in the display apparatus according to another embodiment of the present disclosure, the degree of freedom in the configuration of each driving circuit R-DC, G-DC, W-DC and B-DC and the type of cach thin film transistor TR1, TR2 and TR3 can be improved.

The display apparatus according to the embodiment of the present disclosure is described that the first drain region, the first source region, the second drain region 221d, the second source region 221s, the third drain region and the third source region of each pixel area PA can be used as wiring. However, in the display apparatus according to another embodiment of the present disclosure, the first thin film transistor TR1, the second thin film transistor TR2 and the third thin film transistor TR3 of cach sub-pixel R-SP, G-SP, W-SP and B-SP can have various structures. For example, in the display apparatus according to the embodiment of the present disclosure, the driving circuit R-DC, G-DC, W-DC and B-DC of cach sub-pixel R-SP, G-SP, W-SP and B-SP can include a second drain electrode electrically connected to the second drain region 221d and a second source electrode electrically connected to the second source region 221s. The second drain electrode and the second source electrode of each sub-pixel R-SP, G-SP, W-SP and B-SP can be disposed on a different layer from the second gate electrode 223 of the corresponding sub-pixel R-SP, G-SP, W-SP and B-SP. For example, the second drain electrode and the second source electrode of each sub-pixel R-SP, G-SP, W-SP and B-SP can be disposed between an interlayer insulating layer covering the second gate electrode 223 of the corresponding sub-pixel R-SP, G-SP, W-SP and B-SP and the device passivation layer 130. Thus, in the display apparatus according to another embodiment of the present disclosure, the degree of freedom for the configuration of the driving circuit R-DC, G-DC, W-DC and B-DC in each sub-pixel R-SP, G-SP, W-SP and B-SP can be improved.

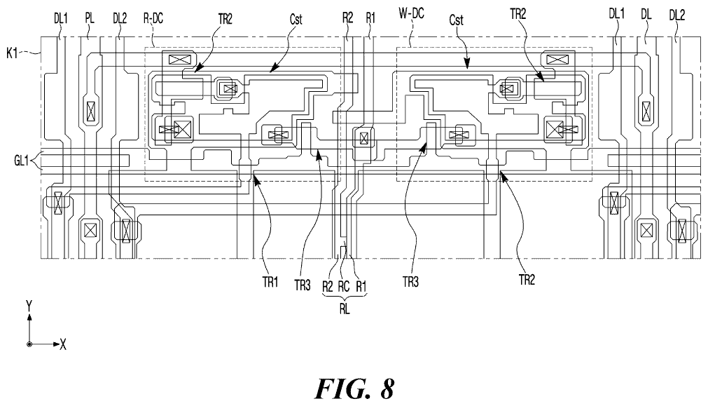

The display apparatus according to the embodiment of the present disclosure is described that each of the reference voltage supply lines RL can be a signal wiring. However, in the display apparatus according to another embodiment of the present disclosure, each of the reference voltage supply lines RL can be formed of multiple wirings. For example, in the display apparatus according to another embodiment of the present disclosure, each of the reference voltage supply lines RL can include a main wiring R1, an auxiliary wiring R2 and a connection wiring Rc, as shown in FIGS. 7 and 8. The auxiliary wiring R2 can extend parallel to the main wiring R1. The auxiliary wiring R2 can be spaced apart from the main wiring R1. The connection wiring Rc can be disposed between the main wiring R1 and the auxiliary wiring R2. The connection wiring Rc can be in direct contact with a portion of the main wiring R1 and a portion of the auxiliary wiring R2. For example, the auxiliary wiring R2 can be in direct contact with the main wiring R1 by the connection wiring Rc. The auxiliary wiring R2 and the connection wiring Rc can include the same or substantially the same material as the main wiring R1. For example, the auxiliary wiring R2 and the connection wiring Rc can be disposed on a same layer as the main wiring R1. The auxiliary wiring R2 and the connection wiring Rc can be formed by the same or substantially the same process as the main wiring R1. For example, the auxiliary wiring R2 and the connection wiring Rc can be formed simultaneously with the main wiring R1.

The third drain region of each sub-pixel R-SP, G-SP, W-SP and B-SP can be electrically connected to the main wiring R1 of the corresponding reference voltage supply line RL. The first electrode 310 of each sub-pixel R-SP, G-SP, W-SP and B-SP can include a portion crossing with the auxiliary wiring R2 of the corresponding reference voltage supply line RL. For example, the auxiliary wiring R2 of each reference voltage supply line RL can be used in a repair process. The repair process can include a process of disconnecting the auxiliary wiring R2 and the connection wiring Rc of some of the reference voltage supply lines RL. For example, the red driving circuit R-DC of each pixel area PA can be electrically connected to the red light-emitting device 300R disposed in the red sub-pixel R-SP of adjacent pixel area PA through the auxiliary wiring R2 of the corresponding reference voltage supply line RL, which is separated by the repair process. Thus, in the display apparatus according to another embodiment of the present disclosure, the repair process can be simplified. Therefore, in the display apparatus according to another embodiment of the present disclosure, the production energy can be effectively reduced by process optimization.

In the result, the display apparatus according to the embodiments of the present disclosure can comprise the pixel areas disposed between the first gate line and the second gate line, wherein each of the pixel areas can include the first sub-pixel and the second sub-pixel, wherein the data line overlapping the first gate line and the second gate line can cross the second sub-pixel of each pixel area and the first sub-pixel of adjacent pixel area, and wherein the second driving circuit of the second sub-pixel disposed close to the second gate line can have an arrangement to be symmetrical to the first driving circuit of the first sub-pixel disposed close to the first gate line. Thus, in the display apparatus according to the embodiments of the present disclosure, the difference between the coupling capacitance of the first sub-pixel in each pixel area and the coupling capacitance of the second sub-pixel in each pixel area can be reduced. Thereby, in the display apparatus according to the embodiments of the present disclosure, the light emitted from the second sub-pixel of each pixel area can have substantially a same luminance as the light emitted from the first sub-pixel of each pixel area. That is, in the display apparatus according to the embodiments of the present disclosure, the degradation in the quality of the image due to the difference in the luminance between the first sub-pixel and the second sub-pixel of each pixel area can be reduced or prevented. And, in the display apparatus according to the embodiments of the present disclosure, the production energy can be reduced by process optimization.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first gate line extending in a first direction;
a first data line extending in a second direction transverse to the first direction, the first data line crossing the first gate line;
a second gate line extending parallel to the first gate line, the second gate line crossing the first data line;
a first sub-pixel including a first driving circuit, the first driving circuit electrically connected to the first gate line and the first data line; and
a second sub-pixel including a second driving circuit, the second driving circuit electrically connected to the first data line and the second gate line,
wherein the first data line crosses between the first sub-pixel and the second sub-pixel,
wherein a second emission area of the second sub-pixel disposed between the first gate line and the second driving circuit displays a different color from a first emission area of the first sub-pixel disposed between the first driving circuit and the second gate line, and
wherein the second driving circuit has a symmetrical arrangement with the first driving circuit.

2. The display apparatus according to claim 1, wherein the second emission area is disposed in the first direction with the first emission area.

3. The display apparatus according to claim 1, wherein each of the first driving circuit and the second driving circuit includes a driving thin film transistor, and
wherein a gate electrode of the driving thin film transistor is disposed parallel to the first gate line and the second gate line.

4. The display apparatus according to claim 3, wherein a semiconductor pattern of the driving thin film transistor is disposed parallel to the first data line.

5. The display apparatus according to claim 1, further comprising:
a second data line disposed parallel to the first data line;
a third sub-pixel including a third driving circuit, the third driving circuit electrically connected to the first gate line and the second data line; and
a fourth sub-pixel including a fourth driving circuit, the fourth driving circuit electrically connected to the second data line and the second gate line,
wherein the first sub-pixel is disposed between the second data line and the third sub-pixel,
wherein the fourth sub-pixel is disposed between the second sub-pixel and the first data line, and
wherein the fourth driving circuit disposed in a first direction with the second driving circuit has a symmetrical arrangement with the third driving circuit disposed in the first direction with the first driving circuit.

6. The display apparatus according to claim 5, wherein the third driving circuit has a symmetrical arrangement with the first driving circuit, and the fourth driving circuit has a symmetrical arrangement with the second driving circuit.

7. The display apparatus according to claim 5, wherein a third emission area of the third sub-pixel disposed between the third driving circuit and the second gate line displays a different color from the first emission area and the second emission area, and
wherein a fourth emission area of the fourth sub-pixel disposed between the first gate line and the fourth driving circuit displays a different color from the first emission area, the second emission area, and the third emission area.

8. The display apparatus according to claim 7, further comprising reference voltage supply lines disposed parallel to the first data line and the second data line,
wherein the first sub-pixel and the third sub-pixel are disposed between one of the reference voltage supply lines and the second data line, and
wherein the second sub-pixel and the fourth sub-pixel are disposed between one of the reference voltage supply lines and the first data line.

9. A display apparatus comprising:
first data lines crossing a first gate line;
second data lines disposed between the first data lines, the second data lines crossing the first gate line;
a second gate line extending parallel to the first gate line, the second gate line crossing the first data lines and the second data lines; and
pixel areas disposed between the first data lines and the second data lines, each of the pixel areas including a first sub-pixel and a second sub-pixel disposed along the first gate line and the second gate line,
wherein a first emission area of the first sub-pixel is disposed between a first driving circuit of the first sub-pixel and the second gate line,
wherein a second emission area of the second sub-pixel is disposed between the first gate line and a second driving circuit of the second sub-pixel, and
wherein the second driving circuit electrically connected to one of the second data lines and the second gate line has a symmetrical arrangement with the first driving circuit electrically connected to one of the first data lines and the first gate line.

10. The display apparatus according to claim 9, wherein the second sub-pixel of each pixel area displays a different color from the first sub-pixel of the corresponding pixel area,
wherein the first sub-pixel of each pixel area displays a same color as the first sub-pixel of adjacent pixel area, and
wherein the second sub-pixel of each pixel area displays a same color as the second sub-pixel of adjacent pixel area.

11. The display apparatus according to claim 9, wherein each of the first sub-pixel and the second sub-pixel in each pixel area includes a first switching thin film transistor and a second switching thin film transistor, and
wherein a semiconductor pattern of the first switching thin film transistor crosses the first gate line or the second gate line.

12. The display apparatus according to claim 11, wherein the first emission area and the second emission area of each pixel area are disposed between the first gate line and the second gate line.

13. The display apparatus according to claim 11, wherein a gate electrode of the second switching thin film transistor has a shape protruding from the first gate line or the second gate line.

14. The display apparatus according to claim 13, wherein a semiconductor pattern of the second switching thin film transistor is disposed parallel to the first gate line and the second gate line.

15. The display apparatus according to claim 9, further comprising reference voltage supply lines disposed between the first data lines and the second data lines, the reference voltage supply lines crossing the first gate line and the second gate line, wherein each of the reference voltage supply lines crosses between the first sub-pixel and the second sub-pixel in one of the pixel areas.

16. The display apparatus according to claim 15, wherein each of the reference voltage supply lines includes a main wiring, an auxiliary wiring disposed parallel to the main wiring, and a connection wiring disposed between the main wiring and the auxiliary wiring,
wherein the auxiliary wiring is electrically connected to the main wiring through the connection wiring,
wherein each of the first sub-pixel and the second sub-pixel includes a light-emitting device overlapping with the corresponding emission area, and
wherein a first electrode of each light-emitting device includes a portion overlapping with the auxiliary wiring.
